(19) United States
(12) Patent Application Publication
(10) Pub. No.: US 2025/0162874 A1
(43) Pub. Date: May 22, 2025

(54) METHOD FOR PREPARING NANOTUBE ARRAY, NANOTUBE ARRAY AND DEVICE

(71) Applicants: ZHEJIANG UNIVERSITY, Hangzhou (CN); BEIJING INSTITUTE OF CARBON-BASED INTEGRATED CIRCUITS, Beijing (CN)

(72) Inventors: Chuanhong JIN, Hangzhou (CN); Bo WANG, Hangzhou (CN); Xibiao REN, Hangzhou (CN); Zhiyong ZHANG, Beijing (CN)

(21) Appl. No.: 19/022,788

(22) Filed: Jan. 15, 2025

Related U.S. Application Data
(63) Continuation of application No. PCT/CN2023/120859, filed on Sep. 22, 2023.

(30) Foreign Application Priority Data
Sep. 6, 2023 (CN) 202311148341.9

(51) Int. Cl. C01B 32/174; C01B 32/194; H10D 30/01; H10D 30/47; H10D 62/10; H10D 62/17; H10D 62/80

(52) U.S. Cl. CPC C01B 32/174; C01B 32/194; H10D 30/017; H10D 30/481; H10D 62/119; H10D 62/235; H10D 62/882; C01B 2202/02; C01B 2202/08; C01B 2202/22; C01B 2204/04; C01B 2204/06; C01B 2204/22; C01P 2004/13; C01P 2004/17

(57) ABSTRACT

Provided are a method for preparing a nanotube array, a nanotube array and a device. The method includes: preparing a double-layer two-dimensional material with a relative angle of lattice orientations, which is used as a template; determining the chiral parameters of nanotubes to be prepared corresponding to the relative angle of the lattice orientations of the double-layer two-dimensional material, determining a nanoribbon orientation and a nanoribbon width according to the determined chiral parameters, determining the inter-nanoribbon spacing according to the density of the nanotubes to be prepared and the nanoribbon width, and etching the double-layer two-dimensional material according to the determined nanoribbon orientation, nanoribbon width and inter-nanoribbon spacing to obtain a nanoribbon array of the double-layer two-dimensional material; and performing thermal excitation treatment on the obtained nanoribbon array of the double-layer two-dimensional material to obtain a nanotube array. The present disclosure can prepare a nanotube array with controllable density, orientation and chirality.

### CROSS-REFERENCE TO RELATED APPLICATIONS

This application is a continuation of International Application No. PCT/CN2023/120859, filed on Sep. 22, 2023, which claims priority of Chinese Patent Application No. CN202311148341.9 filed on Sep. 6, 2023, which are hereby incorporated by reference in their entireties.

### TECHNICAL FIELD

The present disclosure relates to the technical field of nano material preparation and semiconductors and, in particular, to a nanotube array, a method for preparing a nanotube array and a device.

### BACKGROUND

Single-walled carbon nanotubes (hereinafter referred to as carbon tubes) can be regarded as quasi-one-dimensional structures formed by the curling of graphene. Depending on the curling method (chirality), single-walled carbon tubes can show metallic or semiconductor properties. High-density (more than 125 per micron) parallel-arranged semiconductor single-walled carbon tube arrays with full-semiconductor properties are the core materials for building high-performance carbon-based transistors and integrated circuits.

At present, there are mainly two types of preparation methods for single-walled carbon tubes: the first type is catalyst-assisted chemical vapor deposition method (for example, see the following references, Reference 1: Zhang S et al., Nature, 2017, 543:234-238; and Reference 2: Wang J et al., Nature Catalysis, 2018, 1:326-331.), and this method can directly grow full-semiconductor, or even single-chirality single-walled carbon tube arrays. However, this method has the disadvantages of overhigh synthesis temperature, incompatibility with integrated circuit processes, and low array density. The second type is the solution separation and assembly arrangement method. A typical solution is to obtain a single-walled carbon tube solution by polymer dispersion, realize separation of metallic single-walled carbon tubes and semiconductor single-walled carbon tubes by density gradient centrifugation and the like, and then perform self-assembly to obtain a carbon nanotube array wafer (for example, see the following references, Reference 3: Liu L et al., Science, 2020, 368:850-856; and Reference 4: Jinkins K R et al., Science advances, 2021, 7 (37): eabh0640.). This type of method can meet the performance index requirements of advanced technology nodes in terms of the purity and density of semiconductor carbon tubes, but it will introduce polymer residues which are difficult to control, and the arrangement of carbon tubes will also have inhomogeneities such as local agglomeration and stacking. Moreover, this type of method currently still lacks effective control over the chirality of carbon tubes, that is, the chirality of carbon tubes is randomly distributed.

In summary, the current carbon tube array preparation technology still has many difficulties and challenges. It is difficult to ensure the density, orientation, chirality control and cleanliness of the carbon tube array simultaneously, so that the requirements for high orientation, high density, full semiconductor property and high cleanliness of carbon nanotube arrays cannot be met simultaneously when carbon nanotube arrays are used to construct high-performance carbon-based transistors and integrated circuits, thus affecting the realization of high-performance carbon-based transistors and integrated circuits.

### SUMMARY

In view of this, the embodiments of the present disclosure provide a method for preparing a nanotube array, a nanotube array and a device to eliminate or alleviate one or more defects existing in the prior art.

In one aspect of the present disclosure, provided is a method for preparing a nanotube array, including:
a template preparation step: preparing a double-layer two-dimensional material with a relative angle of lattice orientations on a substrate, the double-layer two-dimensional material being used as a template;
a nanoribbon array etching step: determining chiral parameters of nanotubes to be prepared corresponding to the relative angle of the lattice orientations of the double-layer two-dimensional material, determining a nanoribbon orientation and a nanoribbon width according to the determined chiral parameters, determining the inter-nanoribbon spacing according to the density of the nanotubes to be prepared and the nanoribbon width, and etching the double-layer two-dimensional material according to the determined nanoribbon orientation, nanoribbon width and inter-nanoribbon spacing to obtain a nanoribbon array of the double-layer two-dimensional material; and
a nanotube array generation step: performing thermal excitation treatment on the obtained nanoribbon array of the double-layer two-dimensional material to obtain a nanotube array.

In some embodiments of the present disclosure, the preparing a double-layer two-dimensional material with a relative angle of lattice orientations on a substrate includes: preparing a double-layer two-dimensional material with a relative angle of lattice orientations on a substrate by using mechanical exfoliation combined with angle-controllable transfer or using liquid phase transfer combined with angle-controllable transfer; or obtaining a single-layer two-dimensional material by mechanical exfoliation or liquid phase transfer, and folding the obtained single-layer two-dimensional material according to a set orientation to obtain a double-layer two-dimensional material with a relative angle of lattice orientations; or directly growing a double-layer two-dimensional material with a relative angle of lattice orientations by a growth method, wherein the growth method includes one of the following: chemical vapor deposition, molecular beam epitaxy, or physical vapor deposition.

In some embodiments of the present disclosure, the etching the double-layer two-dimensional material according to the determined nanoribbon orientation, nanoribbon width and inter-nanoribbon spacing includes: etching the double-layer two-dimensional material according to the determined nanoribbon orientation, nanoribbon width and inter-nanoribbon spacing by laser lithography, electron beam lithography, focused ion beam, high-energy electron beam, mask method or chemical etching.

In some embodiments of the present disclosure, the thermal excitation treatment includes one or more of the following treatments: annealing, laser excitation, Joule heating and high-energy ray irradiation.

In some embodiments of the present disclosure, at least one layer of two-dimensional material in the double-layer two-dimensional material is ap-type doped or n-type doped two-dimensional material.

In some embodiments of the present disclosure, at least one layer of two-dimensional material in the double-layer two-dimensional material is a two-dimensional material with grain boundaries; different regions of a same double-layer two-dimensional material prepared in the template preparation step have different relative angles of lattice orientations, and/or different sections of a same double-layer two-dimensional material nanoribbon in a lengthwise direction in the nanoribbon array etching step correspond to different nanoribbon widths; the nanotube array obtained in the nanotube array generation step is an array of spliced nanotubes of different chirality.

In some embodiments of the present disclosure, the nanoribbon array etching step further includes: determining a nanoribbon length according to the length of a nanotube to be prepared; the etching the double-layer two-dimensional material according to the determined nanoribbon orientation, nanoribbon width, and inter-nanoribbon spacing includes: etching the double-layer two-dimensional material according to the determined nanoribbon orientation, nanoribbon width, inter-nanoribbon spacing, and nanoribbon length.

In some embodiments of the present disclosure, the double-layer two-dimensional material is double-layer graphene, and the obtained nanotube array is a carbon nanotube array.

In some embodiments of the present disclosure, the double-layer two-dimensional material is a double-layer boron nitride two-dimensional material, a double-layer molybdenum sulfide two-dimensional material, a double-layer molybdenum selenide two-dimensional material or a double-layer tungsten sulfide two-dimensional material; the obtained nanotube array is a boron nitride nanotube array, a molybdenum sulfide nanotube array, a molybdenum selenide nanotube array or a tungsten sulfide nanotube array.

In some embodiments of the present disclosure, the nanoribbon orientation is given by an orientation formula as follows:

$${ψ}_{0} = 30 - arccos ( ( 2 n + m ) / 2 \sqrt{( {n}^{2} + mn + {m}^{2} )} ) ;$$

the nanoribbon width is given by a width formula as follows: w=0.5*a*\sqrt{n²+nm+m²};
where ψ₀ is the nanoribbon orientation, w is the nanoribbon width, a is the lattice constant of the two-dimensional material, and n and m are the chiral indices of a nanotube; or
the nanoribbon orientation and the nanoribbon width are obtained by introducing deviations into the orientation formula and the width formula, respectively.

Another aspect of the present disclosure further provides a nanotube array prepared by the method described above.

Another aspect of the present disclosure further provides a semiconductor device (such as a carbon nanotube transistor) prepared using the nanotube array described above.

The method for preparing a nanotube array according to the present disclosure can prepare a nanotube array with controllable density, orientation and chirality.

Further, in some embodiments, a high-density, high-orientation, full-semiconductor single-walled carbon nanotube array with controllable chirality can be prepared. Due to the controllable density, the carbon nanotubes are evenly distributed without aggregation or stacking.

Additional advantages, objectives, and features of the present disclosure will be set forth in part in the following description, and will in part become apparent to those skilled in the art after studying the following or may be learned from practice of the present disclosure. The objectives and other advantages of the present disclosure can be achieved and obtained by the structures specifically indicated in the specification and the drawings.

Those skilled in the art will understand that the objectives and advantages that can be achieved with the present disclosure are not limited to those specifically described above, and the above and other objectives that can be achieved with the present disclosure will be more clearly understood based on the following detailed description.

### BRIEF DESCRIPTION OF DRAWINGS

The drawings described herein are used to provide further understanding of the present disclosure, constitute a part of the present application, and do not constitute a limitation on the present disclosure. In the drawings:

FIG. 1 is a schematic diagram of the chirality of carbon nanotubes.

FIGS. 2A-2C are schematic diagrams of a geometric relationship between a double-layer graphene nanoribbon and the chirality of carbon nanotubes in an embodiment of the present disclosure.

FIG. 3 is a schematic flowchart of a method for preparing a nanotube array in an embodiment of the present disclosure.

FIG. 4 is a schematic diagram of a process of preparing a carbon nanotube array in an embodiment of the present disclosure.

### DESCRIPTION OF EMBODIMENTS

In order to make the objective, technical solution and advantages of the present disclosure more clear, the present disclosure is further described in detail below in conjunction with embodiments and the accompanying drawings. Here, the schematic embodiments and the description of the present disclosure are used to explain the present disclosure, but are not intended to limit the present disclosure.

It should also be noted that, in order to avoid obscuring the present disclosure due to unnecessary details, only the structures and/or processing steps closely related to the solution according to the present disclosure are shown in the drawings, while other details that are not closely related to the present disclosure are omitted.

It should be emphasized that the term “include/comprise”, when used herein, refers to the presence of features, elements, steps or components, but does not exclude the presence or addition of one or more other features, elements, steps or components.

It should also be noted that, if not specifically stated, the term “connect” used herein refers not only to direct connection, but also to indirect connection with the presence of an intermediate.

Embodiments of the present disclosure will be described below with reference to the drawings. In the drawings, the same reference numerals represent the same or similar parts, or the same or similar steps.

It should be emphasized here that the step marks mentioned below are not limitations on the order of the steps, but should be understood that the steps can be performed in the order mentioned in the embodiment, or in a different order from the embodiment, or several steps can be performed simultaneously.

For the existing carbon nanotube arrays, their density, orientation and chirality are difficult to be controlled simultaneously, resulting in problems of uneven distribution or inconsistent chirality, such as uneven array orientation, local agglomeration or stacking, or other problems. To solve these problems, the present disclosure provides a novel method for preparing a single-walled carbon nanotube array with controllable chirality based on double-layer graphene. The method of the present disclosure is a novel top-down means for selecting and controlling the chirality of carbon nanotubes (or carbon tubes for short), which can adjust the density ρ of a single-walled carbon nanotube array within the following range: 0<ρ≤350 tubes/μm, and also can keep single-walled carbon nanotubes in the array highly consistent in orientation. In addition, the method of the present disclosure can control the chirality of the carbon nanotubes. That is, the method can manufacture single-walled carbon nanotubes with specific chirality. Further, metal-semiconductor junctions or chiral junctions with different bandgaps can be introduced as needed to meet the needs of high-performance carbon nanotube transistors and integrated circuits for channel materials.

The following describes the principle of the method for preparing a carbon nanotube array according to the present disclosure firstly by taking the preparation of a single-walled carbon tube using double-layer graphene as an example, and then describes the method for preparing a carbon nanotube array according to the present disclosure in detail.

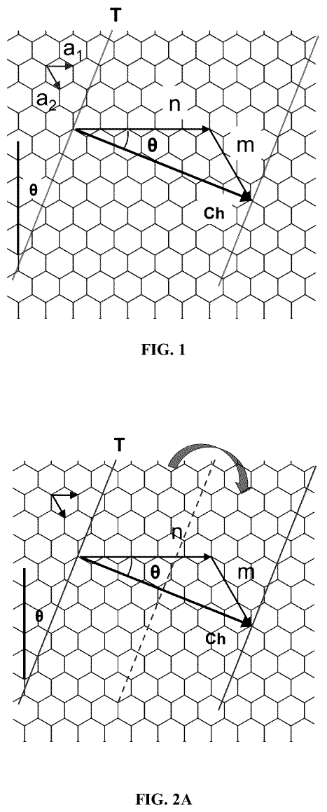

As shown in FIG. 1, the geometric structure of a single-walled carbon nanotube can be regarded as a layer of graphene curled along a chiral vector Ch. Depending on the direction and value of the chiral vector Ch, the curled carbon nanotubes have different chirality, which can also be represented by Ch. The vectors a₁ and a₂ indicated by arrows in FIG. 1 represent the basis vectors of a single-layer graphene lattice. An example where two zigzag edges of graphene are used as basis vectors is set forth herein to describe the geometric relationships involved in the present disclosure, including but not limited to angle relationships and length relationships. The principle derivations with different geometric descriptions but equivalent structures due to different selection methods of basis vectors are also covered within the scope of the present disclosure.

The chiral vector Ch of a carbon nanotube can be represented by basis vectors a₁ and a₂. When Ch=na₁+ma₂, the chirality of the carbon nanotube is (n, m). The electronic structure of a carbon nanotube is related to the chiral indices of the carbon nanotube. When n-m is divisible by 3, the carbon nanotube exhibits metallic properties; when n-m is not divisible by 3, the carbon nanotube exhibits semiconductor properties. Also, the bandgap of a carbon tube is also affected by the value of Ch. The larger the Ch, the smaller the bandgap. Given that, by controlling the chirality of a carbon nanotube, the electronic structure of the carbon nanotube can be controlled. As shown in FIG. 1, θ represents an angle between the chiral vector and the basis vector of graphene, and T represents the radial direction of carbon nanotubes.

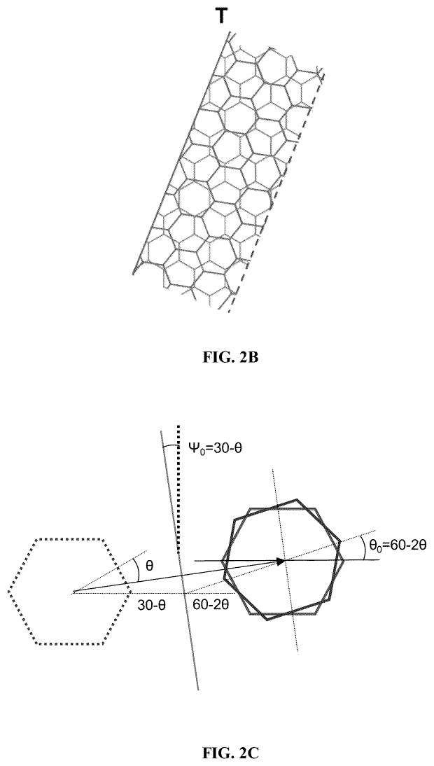

As shown in FIG. 2A, when a single layer of graphene is folded in half along ½Ch, a double-layer graphene nanoribbon shown in FIG. 2B can be obtained. The geometric topology of the double-layer graphene nanoribbon is not changed as compared with that of the single layer of graphene before folding. If carbon atoms in the upper and lower layers on the two sides of the double-layer graphene nanoribbon are connected and the entire planar double-layer structure is bulged into a cylindrical shape, thus a carbon nanotube with a chiral vector Ch is obtained. The inventors of the present disclosure find that edges of the double-layer graphene will form a bulging closed structure under annealing conditions. Based on this phenomenon, the inventors of the present disclosure innovatively use double-layer graphene as a template for preparing a parallel array of carbon tubes, and then perform etching to transform the double-layer graphene into a double-layer graphene nanoribbon array of which the orientation and width match the chiral parameters of the carbon tubes, and carry out a thermal excitation treatment such as annealing to transform the double-layer graphene nanoribbon array into a single-walled carbon nanotube array. Therefore, the present disclosure provides a method for obtaining a carbon nanotube with a certain target chirality by preparing a double-layer graphene nanoribbon with a specific relative angle and a specific width, followed by thermal excitation treatment (such as annealing).

The chirality of the carbon nanotube is determined by the relative angle θ₀ between lattice orientations of two layers of graphene and the nanoribbon width w. Referring to FIGS. 2A-2C, for a carbon nanotube with target chirality vector Ch, direction θ, and value |Cₕ|, according to derivation of geometric relationships, the relationship between the target chirality (n, m) of the carbon nanotube and the width w of the double-layer graphene nanoribbon and the relationship between the target chirality (n, m) of the carbon nanotube and the relative angle θ₀ between lattice orientations of two layers of graphene (i.e., the angle between the basis vectors of the two layers of graphene) are as follows (Formula Group 1):

$${θ}_{0} = 60 - 2 * θ ;$$

$$w = 0.5 * \vert {C}_{h} \vert ;$$

where the relative angle θ₀ between lattice orientations of two layers of graphene determines the direction of the chiral vector Ch of the carbon nanotube (i.e., the angle θ between the chiral vector and the basis vector of graphene), and the width w of the double-layer nanoribbon determines the value |Cₕ| of the chiral vector Ch of the carbon nanotube. The relationship between the chiral indices (n, m) and the direction of the chiral vector and the relationship between the chiral indices (n, m) and value of the chiral vector are as follows (Formula Group 2):

$$θ = arccos ( ( 2 n + m ) / ( 2 \sqrt{( {n}^{2} + nm + {m}^{2} )} ) ) ;$$

$${d}_{t} = \vert {C}_{h} \vert / π = a / π * \sqrt{{n}^{2} + nm + {m}^{2}} ;$$

where a is the lattice constant of graphene, dₜ is the diameter of the target carbon tube, and by substituting values of θ and |Ch| into Formula Group 1, the relationship between the width w of the double-layer graphene nanoribbon and the chiral indices (n, m) of the target carbon tube and the relationship between the relative angle θ₀ of the interlayer lattice orientations and the chiral indices (n, m) of the target carbon tube are obtained as follows (Formula Group 3):

$$w = 0.5 * a * \sqrt{{n}^{2} + nm + {m}^{2}} = 0.5 * {d}_{t} * π ;$$

$${θ}_{0} = 60 - 2 * arccos ( ( 2 n + m ) / ( 2 \sqrt{( {n}^{2} + nm + {m}^{2} )} ) ) ;$$

According to the relationships in the above formulas, the present disclosure designs a double-layer graphene nanoribbon with a specific relative angle θ₀ and a specific width w, and performs annealing or other heat treatments on the double-layer graphene nanoribbon to obtain a carbon nanotube with corresponding chirality.

The method of the present disclosure is not limited to the preparation of a single-walled carbon nanotube array. Since the edges of double-layer two-dimensional material nanoribbons generally close after annealing, by replacing the double-layer graphene with other two-dimensional material templates, the method designed by the present disclosure can also be applied to the production and processing of other one-dimensional nanotubes and arrays of the one-dimensional nanotubes. For example, boron nitride nanotube arrays, molybdenum sulfide nanotube arrays, molybdenum selenide nanotube arrays, tungsten sulfide nanotube arrays and other nanotube arrays may be prepared based on double-layer boron nitride two-dimensional material, double-layer molybdenum sulfide two-dimensional material, double-layer molybdenum selenide two-dimensional material and double-layer tungsten sulfide two-dimensional material respectively. To calculate the orientation and width of a nanoribbon to be obtained by etching, the lattice constant a of graphene in the previous formulas needs to be replaced with the lattice constant of a corresponding crystal. These novel one-dimensional nanotube arrays also have the advantages of accurately controlled array density, orientation, and chirality. The nanotube arrays listed here are only examples, and the present disclosure is not limited thereto.

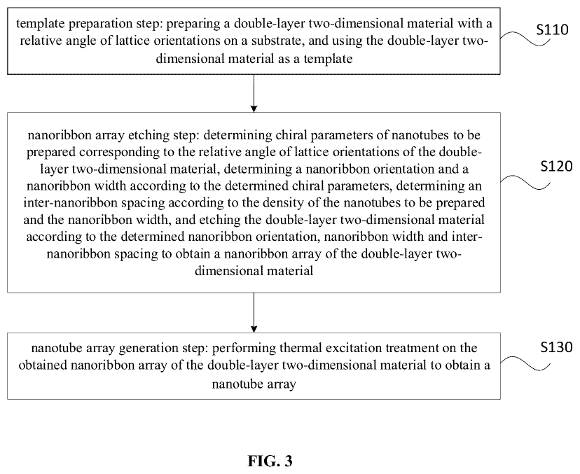

FIG. 3 is a schematic flowchart of the method for preparing a nanotube array in an embodiment of the present disclosure. As shown in FIG. 3, the method includes the following steps S110 to S130:

A template preparation step S110: preparing a double-layer two-dimensional material with a relative angle of lattice orientations on a substrate, the double-layer two-dimensional material being used as a template.

When the two-dimensional material is graphene, this method corresponds to the preparation of a single-walled carbon nanotube. In an embodiment of the present disclosure, there is no special requirement for the selection of the substrate, and in principle, the substrate should withstand the annealing temperature. However, since the nanotubes prepared by the method of the present disclosure have high cleanliness and can be used for the preparation of high-performance semiconductor devices, from the perspective of convenience for the subsequent direct preparation of semiconductor devices, the substrate can be a surface-insulated substrate, such as a surface-insulated silicon substrate, and more specifically, a silicon wafer covered with silicon dioxide, but the present disclosure is not limited thereto.

A nanoribbon array etching step S120: determining the chiral parameters of nanotubes to be prepared corresponding to the relative angle of the lattice orientations of the double-layer two-dimensional material, determining a nanoribbon orientation and a nanoribbon width according to the determined chiral parameters, determining the inter-nanoribbon spacing according to the density of the nanotubes to be prepared and the nanoribbon width, and etching the double-layer two-dimensional material according to the determined nanoribbon orientation, nanoribbon width and inter-nanoribbon spacing to obtain a nanoribbon array of the double-layer two-dimensional material.

A nanotube array generation step S130: performing thermal excitation treatment on the obtained nanoribbon array of the double-layer two-dimensional material to obtain a nanotube array.

Based on the above steps, a nanotube array with a determined chirality can be obtained.

In step S110, the double-layer two-dimensional material with a relative angle of lattice orientations prepared on the substrate is used as a template. When the preparation method is used to prepare single-walled carbon nanotubes, the double-layer two-dimensional material used as a template is double-layer graphene.

For a carbon nanotube array with a specified chirality (n, m), according to the relationship between the relative angle θ₀ of two layers of graphene and the chiral indices (n, m) in Formula Group 3, it is necessary to prepare double-layer graphene with a relative interlayer rotation angle θ₀ firstly. There are many methods for preparing double-layer graphene with a relative interlayer rotation angle θ₀, such as, including: (1) mechanical exfoliation combined with angle-controllable transfer method (mechanical exfoliation+angle-controllable transfer method); (2) liquid phase transfer combined with angle-controllable transfer method (liquid phase transfer+angle-controllable transfer method); or (3) a single-layer graphene folding method.

### (1) Mechanical Exfoliation+Angle-Controllable Transfer Method

The preparation of a double-layer graphene by a mechanical exfoliation+angle-controllable transfer method refers to: firstly performing mechanical exfoliation method twice to obtain two single-layer graphenes, and then using an angle-controllable transfer technique to transfer the two single-layer graphenes obtained by the two mechanical exfoliations to a substrate to obtain a double-layer graphene.

The performing mechanical exfoliation method to obtain the single-layer graphene here refers to applying a mechanical force (such as friction and/or tensile force) to graphite crystals to separate a graphene sheet from the graphite crystals. Since the mechanical exfoliation method for obtaining single-layer graphene is an existing mature technology, it will not be described in detail here.

The process of obtaining the double-layer graphene using the angle-controllable transfer technique specifically includes the following steps:
after two single-layer graphenes are obtained by mechanical exfoliation, the two single-layer graphenes are kept on a transparent substrate such as PDMS (polydimethylsiloxane) or PMMA (polymethyl methacrylate) for the subsequent use of an optical rotation angle control console to control the relative interleaved angle of the two single-layer graphenes. Here, the materials used for the transparent substrate are only examples, and the present disclosure is not limited thereto.

In the process of controlling the relative interleaved angle of the two single-layer graphenes by the optical rotation angle control console, the lattice orientations of the two single-layer graphenes are determined and marked by means of angle-resolved Raman, crystallographic structure (such as edge angle) measurement or low-energy electron beam diffraction, and the two single-layer graphenes with determined crystallographic orientations are bonded together at a specific relative angle using the angle-controllable optical rotation angle control console, thereby preparing a double-layer graphene with a specific relative angle of lattice orientations;
then, the obtained double-layer graphene with a specific relative angle of lattice orientations can be transferred to a substrate using a transfer technique such as a dry transfer technique or a wet transfer technique.

### (2) Liquid Phase Transfer+Angle-Controllable Transfer Method

The preparation of a double-layer graphene by liquid phase transfer+angle-controllable transfer method refers to: performing liquid phase transfer twice to obtain two single-layer graphenes, and then using an angle-controllable transfer technique to transfer the two single-layer graphenes obtained by the two liquid phase transfers to a substrate to obtain a double-layer graphene.

The performing liquid phase transfer to obtain single-layer graphenes includes the following steps:

On two substrates each having a single-layer graphene grown by chemical vapor deposition (CVD), molecular beam epitaxy (MBE), chemical vapor transport (CVT) or other methods, liquid phase transfer is performed to obtain two single-layer graphenes. Then, the two obtained single-layer graphenes are kept on a transparent substrate such as PDMS or PMMA for the subsequent use of an angle control console to control the relative interleaved angle.

In the process of controlling the relative interleaved angle of the two single-layer graphenes by an optical rotation angle control console, the lattice orientations of the two single-layer graphenes are determined and marked by means of angle-resolved Raman, crystallographic structure (such as edge angle) measurement or low-energy electron beam diffraction, and the two single-layer graphenes with determined crystallographic orientations are bonded together at a specific relative angle using the angle-controllable optical rotation angle control console, thereby preparing a double-layer graphene with a specific relative angle of lattice orientations;
then, the obtained double-layer graphene with a specific relative angle of lattice orientations can be transferred to a substrate using a transfer technique such as a dry transfer technique or a wet transfer technique.

### (3) Single-Layer Graphene Folding Method

A single-layer graphene can be obtained by mechanical exfoliation or liquid phase transfer, and then the obtained single-layer graphene is folded according to a set orientation to obtain a double-layer two-dimensional material with a relative angle of lattice orientations.

It is also possible to directly grow a double-layer two-dimensional material with a relative angle of lattice orientations by a growth method such as chemical vapor deposition, molecular beam epitaxy, physical vapor deposition or the like method. Using the methods described above, graphene can be replaced with other two-dimensional materials, and a double-layer two-dimensional material with a relative angle of lattice orientations can also be prepared on a substrate. Therefore, similarly, in step S110, a double-layer boron nitride two-dimensional material, a double-layer molybdenum sulfide two-dimensional material, a double-layer molybdenum selenide two-dimensional material or a double-layer tungsten sulfide two-dimensional material can also be obtained on a substrate, and the interlayer relative angle is controllable.

In addition, in an embodiment of the present disclosure, for double-layer graphene with any interlayer relative rotation angle θ₀, such as double-layer graphene obtained by direct growth method, the chiral indices (n, m) that can be processed to meet the electronic structure requirements when the interlayer rotation angle is θ₀ can also be inferred according to an actual required carbon nanotube electronic structure, such as semiconductor-property of carbon nanotubes.

In step S120, before etching to obtain the nanoribbon array, the chiral parameters, such as chiral indices (n, m), of the nanotubes to be prepared need to be determined firstly, and then the orientation of the nanoribbon array to be obtained by etching (i.e., the angle ψ₀ of the nanoribbon array relative to the lattice orientation of the double-layer two-dimensional material) is determined according to the determined chiral parameters of the nanotubes, and the nanoribbon width and the inter-nanoribbon spacing are then further determined.

Taking the etching of a double-layer graphene nanoribbon array as an example, before etching to obtain the double-layer graphene nanoribbon array, the angle ψ₀ of the nanoribbon array to be obtained by etching relative to the lattice of the double-layer graphene needs to be determined firstly. Due to the structural symmetry, the orientation of the nanoribbon should simultaneously satisfy that the angles relative to the basis vector directions of the two layers of graphene are both Vo. Based on the geometric relationships shown in FIGS. 2A-2C, when the angle between the chiral vector Ch and the basis vector a₁ of graphene is θ, we have:

$${ψ}_{0} = 30 - θ = 30 - arccos ( ( 2 n + m ) / 2 \sqrt{( {n}^{2} + mn + {m}^{2} )} ) ;$$

The crystallographic orientation of the double-layer graphene can be determined in a variety of ways, including but not limited to one or a combination of some of the following ways: optical microscopy, scanning electron microscopy, low-energy electron diffraction, electron diffraction, angle-resolved photoelectron spectroscopy, Raman spectroscopy, and high-resolution transmission electron microscopy. According to the determined crystallographic orientation of the double-layer graphene, the angle ψ of the orientation of the nanoribbon array to be obtained by etching relative to the lattice of the double-layer graphene can be determined. That is, the orientation of the double-layer graphene nanoribbon array can be determined.

After the orientation of the double-layer graphene nanoribbon array is determined, the width of a single nanoribbon is determined by w in Formula Group 3, and the inter-nanoribbon spacing Δx is determined by the required carbon nanotube density ρ (the number of carbon nanotubes per unit length) and is expressed as:

$$Δ x = 1 / ρ - w ;$$

From the above formula, it can be seen that the density ρ of the carbon nanotube array can be controlled by adjusting the gap Δx between the double-layer graphene nanoribbons (the width of the gap between the nanoribbons). In addition, when Δx is 0, the carbon nanotube density ρ reaches the maximum value ρₘₐₓ, and the maximum density ρₘₐₓ is also related to the diameter dₜ of the target chiral carbon tube, so the maximum density can be expressed as:

$${ρ}_{max} = 1 / w = 1 / ( 0.5 * {d}_{t} * π ) ;$$

In the present disclosure, the range of the density of carbon nanotubes in the carbon tube array is controlled as 0<ρ<ρₘₐₓ. In addition, the length L of the graphene nanoribbon determines the length of the carbon nanotube formed after annealing, and the length L of the nanoribbon can be selected according to actual experimental requirements.

After the nanoribbon orientation, the nanoribbon width, the inter-nanoribbon spacing and the nanoribbon length are determined, the nanoribbon array can be etched according to these determined parameters. There are many etching methods for double-layer graphene nanoribbon arrays, including but not limited to: laser lithography, electron beam lithography, focused ion beam, high-energy electron beam, mask method, chemical etching, and one etching method can be selected from these methods to etch the nanoribbons.

In a similar manner to etching graphene nanoribbon arrays, nanoribbon arrays of two-dimensional materials, such as two-layer boron nitride nanoribbon arrays, two-layer molybdenum sulfide nanoribbon arrays, two-layer molybdenum selenide nanoribbon arrays, or two-layer tungsten sulfide nanoribbon arrays, can be prepared. These materials are only examples, and the present disclosure is not limited thereto.

Step S130 is also described by taking the thermal excitation treatment of a double-layer graphene nanoribbon array as an example. There are many ways to perform the thermal excitation treatment in this step, as long as sufficient external excitation can be provided to cause the double-layer graphene nanoribbon to undergo edge closure reconstruction. As an example, the thermal excitation treatment may include one or more of the following treatments: annealing, laser excitation, Joule heating, and high-energy ray irradiation, but the present disclosure is not limited thereto.

Taking annealing as an example, in some embodiments of the present disclosure, the temperature of the annealing treatment of the double-layer graphene nanoribbon array may be, for example, between 250° C. and 1300° C., and the range of the annealing time may be, for example, between 0.1 s and 600 s depending on the heating temperature, or the annealing may be performed at different temperatures in different time periods, but the present disclosure is not limited thereto. The annealing treatment of the double-layer graphene nanoribbon array may be performed in vacuum or in inert gas environment.

When other thermal excitation treatment methods such as laser excitation, Joule heating or high-energy ray irradiation are used to replace annealing of the double-layer graphene nanoribbon array, the heating temperature range of these other thermal excitation treatment methods may also be between 250° C. and 1300° C., and the heating time may be, for example, between 0.1 s and 600 s depending on the heating temperature.

After etching, the double-layer graphene nanoribbon has the same orientation ψ, inter-nanoribbon spacing Δx, interlayer relative rotation angle θ₀ and nanoribbon width w. The process of generating a single-walled carbon nanotube by thermal excitation only involves reconstructing and connecting the unsaturated carbon atoms on two sides of the double-layer graphene nanoribbon through thermal excitation. Therefore, the carbon nanotube after thermal excitation has the same orientation ψ as the graphene nanoribbon, and after tube formation, due to change from a planar structure to a tubular structure, the inter-tube spacing Δx_{tube} becomes Δx_{tube}=Δx+w−dₜ. Since all carbon tubes are transformed from double-layer graphene with the same width w and the same relative angle θ₀, each single-walled carbon nanotube in the array has the same chirality (n, m). Therefore, according to the present disclosure, after the double-layer graphene nanoribbon array is thermally excited, an array of single-walled carbon nanotubes with the same orientation ψ (high orientation consistency), the same spacing Δx_{tube} (high uniformity), consistent chirality (n, m) (controllable chirality), and adjustable density (0<ρ<ρₘₐₓ) (that is, high density and adjustable spacing can be achieved).

Moreover, since the method of the present disclosure does not require growth methods such as catalyst-assisted growth, polymer centrifugal pulling or the other growth methods, and means to select and arrange carbon nanotubes, the impurity level only depends on the cleanliness of graphene and the residues caused in conventional semiconductor process flow. Therefore, the prepared carbon nanotube array has a cleanliness level that can meet the requirements for direct use in the preparation of high-performance devices.

Similar to the treatment of the double-layer graphene nanoribbon array, the double-layer nanoribbon arrays of other two-dimensional materials (such as boron nitride nanoribbon arrays, molybdenum sulfide nanoribbon arrays, molybdenum selenide nanoribbon arrays or tungsten sulfide nanoribbon arrays) obtained in step S120 are also thermally excited in the temperature range of 250° C.-1300° C. Since the tube forming temperatures of different materials are different, the temperature of thermal excitation treatment can be adaptively adjusted, and nanotube arrays such as boron nitride nanotube arrays, molybdenum sulfide nanotube arrays, molybdenum selenide nanotube arrays or tungsten sulfide nanotube arrays can also be obtained.

It can be seen from the above that the method of the present disclosure can prepare a carbon nanotube array with high orientation consistency, high density, controllable chirality, adjustable spacing, uniform distribution and high cleanliness using the double-layer graphene as a template. In addition, nanotube arrays of other materials can also be prepared in the same way.

In some embodiments of the present disclosure, one or two layers in the double-layer graphene used to prepare a single-walled carbon nanotube may be replaced with p-type doped graphene or n-type doped graphene. When both two layers are doped, the two layers of graphene may be of the same or different doping types. If the doping types of the two layers of graphene are the same, the carbon nanotube array prepared using such a double-layer graphene as a template is a p-type carbon nanotube array or an n-type carbon nanotube array. If one layer is replaced with p-type doped graphene and the other layer is replaced with n-type doped graphene, the carbon nanotube array prepared using such a double-layer graphene as a template is a carbon nanotube array with radial pn junctions.

In some embodiments of the present disclosure, since the chirality (n, m) of the prepared carbon nanotube is adjusted and controlled by the interlayer relative angle θ₀ of the double-layer graphene nanoribbon and the nanoribbon width w, different relative angles θ₀ and/or widths w may be introduced into the same double-layer graphene nanoribbon, so that spliced carbon nanotubes of different chirality can be formed, and a chiral junction is connected between carbon nanotubes with different chirality. The change of the interlayer rotation angle θ₀ may be caused by the introduction of grain boundaries. In comparison, it is easier to adjust and control the width w of the nanoribbon by changing the etching template. More specifically, by changing one or two layers of graphene in the double-layer graphene into polycrystalline graphene, the graphene nanoribbons on two sides of the grain boundary can have different angles θ₀. For the realization of different widths w, during the etching process, the retained nanoribbon width can be controlled so that different sections of the same double-layer graphene nanoribbon in the lengthwise direction correspond to different nanoribbon widths w.

Expanding to double-layer two-dimensional materials, when at least one layer of two-dimensional material in a double-layer two-dimensional material may be a two-dimensional material with grain boundaries, different regions of the same double-layer two-dimensional material prepared in the template preparation step will have different relative angles of lattice orientations; correspondingly, the nanotube array obtained in the nanotube array generation step is an array of spliced nanotubes of different chirality.

Similar treatments are also applicable to double-layer two-dimensional materials of boron nitride, molybdenum sulfide, molybdenum selenide, tungsten sulfide, and the like.

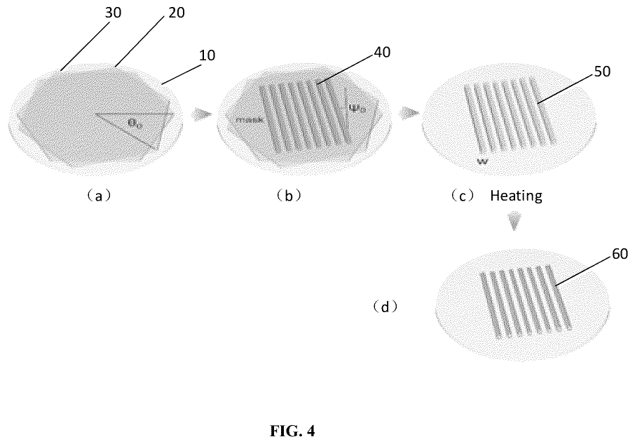

A schematic process for preparing a single-walled carbon nanotube array on a substrate is shown in FIG. 4.

As shown in FIG. 4(a), two layers of graphene 20 and 30 with a relative angle θ₀ of lattice orientations are prepared on a surface-insulated substrate 10 (such as a silicon wafer covered with silicon dioxide). For example, a single-layer graphene 20 is exfoliated from the surface of a graphite crystal by mechanical exfoliation, and the exfoliated single-layer graphene 20 is transferred to the substrate 10 in a predetermined orientation, and then the mechanical exfoliation and transfer steps are performed again to place the newly exfoliated single-layer graphene 30 on the previously exfoliated single-layer graphene 20 to form a stacked double-layer graphene as a template, and the relative angle of lattice orientations between the two layers of graphene is controlled to be θ₀ during the transfer operation. In some embodiments of the present disclosure, θ₀ may be any value between 0° and 360°. In an alternative embodiment of the present disclosure, in the transfer step, two layers of graphene may also be placed on the substrate 10 at an arbitrary angle, and after the double-layer graphene is formed, the crystallographic relative angle can be determined by scanning electron microscopy, transmission electron microscopy, or the like.

FIG. 4(b) shows that the double-layer graphene obtained in (a) is etched using a mask 40 to obtain a double-layer graphene nanoribbon array. First, the nanoribbon orientation (such as the angle ψ₀ between the nanoribbon orientation and the lattice orientations of graphene) and the nanoribbon width are determined according to the chiral parameters corresponding to the relative angle θ₀, the inter-nanoribbon spacing is determined according to the density of carbon tubes to be prepared and the nanoribbon width, and the double-layer graphene is etched according to the determined nanoribbon orientation, nanoribbon width and inter-nanoribbon spacing to obtain a double-layer graphene nanoribbon array 50, as shown in FIG. 4(c). The double-layer graphene nanoribbon array is annealed to obtain a carbon nanotube array 60 shown in FIG. 4(d), where the annealing temperature is between 250° C. and 1300° C., and the annealing time is between 0.1 s and 600 s depending on the annealing temperature.

In the preparation process of the carbon nanotube array of the present disclosure, when there are errors in processing a graphene nanoribbon, such as width error Δw, orientation error Δψ and interlayer relative angle error Δθ₀ of the nanoribbon, topological defects such as 5-8 rings or 5-7-7-5 rings will exist in the formed carbon nanotube due to the inability to maintain perfect connection geometrically. As the errors increase, the mismatch density of the edges of the double-layer graphene nanoribbons will increase accordingly, and the defect density in the formed carbon tubes will also increase. However, since the edges of the double-layer graphene nanoribbon tend to form a closed structure to reduce energy under high-temperature conditions, a carbon tube structure can always be formed. In the case of extreme degradation, if w, ψ₀ and θ₀ are not determined strictly according to the geometric relationships described above, a carbon nanotube array can also be formed, and the carbon nanotube array formed also has the characteristics of uniformity, high density, high cleanliness and adjustable spacing, but loses the controllability of chirality and introduces a large number of topological defects in the carbon nanotubes. However, this degradation technology for preparing carbon nanotube arrays should also be included in the scope of the present disclosure.

Using the geometric relationships between w, ψ₀ and θ₀ in the above formulas, the present disclosure can also construct carbon nanotubes with metal-semiconductor junctions and chiral junctions. In this case, the double-layer graphene comprises two layers of graphene in which at least one layer has grain boundaries, and there are different relative angles between the two layers of graphene of different regions. In addition, in the nanoribbon array etching step, different chiral parameters of a carbon nanotube to be prepared from the double-layer graphene with different relative angles are determined, and nanoribbon orientation and different nanoribbon widths of different sections of the nanoribbon in the lengthwise direction corresponding to the different chiral parameters can be further determined according to the determined different chiral parameters. Described below is an example: Different relative angles θ_{0A}, θ_{0B} and widths w_{A} and w_{B} are introduced into the same double-layer graphene nanoribbon, where the different relative angles are generated by the grain boundaries during graphene growth, and the different widths can be set by the etching parameters during exposure and etching. After this type of double-layer graphene nanoribbon is annealed to form a carbon nanotube, the chiral indices (n_{A}, m_{A}) of the section θ_{0A}, w_{A} and the chiral indices (n_{B}, m_{B}) of the section θ_{0B}, w_{B} can be obtained by the formulas described above, and then a chiral-junction carbon nanotube with different chirality is formed. On the contrary, the present disclosure can also use the formulas to derive the processing parameters θ_{0A}, θ_{0B} and w_{A}, w_{B} according to the pre-designed chiral indices (n_{A}, m_{A}) and (n_{B}, m_{B}). Since the chiral indices determine the metallic and semiconductor properties of the carbon nanotube, when the chirality of one side is metallic carbon nanotube and the chirality of the other side is semiconductor carbon nanotube, a carbon nanotube with metal-semiconductor junctions is formed. The number of chiral junctions and metal-semiconductor junctions depends on how many different sets of processing parameters w, ψ₀ and θ₀ are introduced into the same double-layer graphene ribbon.

The existing technology cannot simultaneously meet the requirements of high orientation consistency, high density, full semiconductor property, adjustable spacing, uniform distribution (uniform spacing of carbon tubes without agglomeration or stacking), and on this basis, there is also a lack of effective means to control the chirality of carbon tubes. The existing CVD method for growing carbon nanotube arrays produces carbon nanotubes with low and uncontrollable density and wide and complex chirality distribution (i.e., uncontrollable chirality), and catalyst residues. The existing liquid phase pulling method for preparing carbon nanotube arrays produces carbon nanotubes with too high and uncontrollable density, and can only obtain chirality with semiconductor property (that is, chirality is not completely controllable) and complex nanotube orientation with stacking, and the prepared carbon nanotubes are contaminated by polymers. In contrast, the carbon nanotubes prepared by the method for preparing carbon nanotubes according to the present disclosure have controllable density and chirality, and the method of the present disclosure can prepare both semiconductor carbon nanotubes and metallic carbon nanotubes. In addition, the inter-tube spacing is uniform and the surface is clean. Therefore, the method of the present disclosure can provide a single-walled carbon nanotube array that meets the requirements of controllable density, orientation and chirality, and the cleanliness of the prepared single-walled carbon nanotube array meets the requirements of carbon nanotube (CNT) transistors and integrated circuits thereof for carbon nanotube materials.

By using the carbon nanotube array with better performance prepared by the above method to construct a carbon nanotube transistor, device performance loss caused by carbon nanotube stacking, surface dirt, and uneven distribution of tube diameter can be avoided, and a carbon nanotube transistor with better performance can be obtained.

It should be clear that the present disclosure is not limited to the specific configuration and processing described above and shown in the figures. For the sake of simplicity, a detailed description of the known method is omitted here. In the above embodiments, several specific steps are described and shown as examples. However, the method process of the present disclosure is not limited to the specific steps described and shown. Those skilled in the art can make various changes, modifications and additions, or change the order of the steps after understanding the spirit of the present disclosure.

In the present disclosure, the features described and/or illustrated for one embodiment may be used in the same manner or in a similar manner in one or more other embodiments, and/or combined with or replace the features of other embodiments.

The above are only preferred embodiments of the present disclosure and are not intended to limit the present disclosure. For those skilled in the art, the embodiments of the present disclosure may have various modifications and changes. Any modification, equivalent replacement, improvement, etc. made within the spirit and principle of the present disclosure shall fall within the scope of the present disclosure.

What is claimed is:

1. A method for preparing a nanotube array, the method comprises the following steps:
a template preparation step: preparing a double-layer two-dimensional material with a relative angle of lattice orientations on a substrate, the double-layer two-dimensional material being used as a template;
a nanoribbon array etching step: determining chiral parameters of nanotubes to be prepared corresponding to the relative angle of lattice orientations of the double-layer two-dimensional material, determining a nanoribbon orientation and a nanoribbon width according to the determined chiral parameters, determining an inter-nanoribbon spacing according to the density of the nanotubes to be prepared and the nanoribbon width, and etching the double-layer two-dimensional material according to the determined nanoribbon orientation, nanoribbon width and inter-nanoribbon spacing to obtain a nanoribbon array of the double-layer two-dimensional material; and
a nanotube array generation step: performing thermal excitation treatment on the obtained nanoribbon array of the double-layer two-dimensional material to obtain a nanotube array.

2. The method according to claim 1, wherein the preparing a double-layer two-dimensional material with a relative angle of lattice orientations on a substrate comprises:
preparing a double-layer two-dimensional material with a relative angle of lattice orientations on a substrate by using mechanical exfoliation combined with angle-controllable transfer or using liquid phase transfer combined with angle-controllable transfer; or
obtaining a single-layer two-dimensional material by mechanical exfoliation or liquid phase transfer, and folding the obtained single-layer two-dimensional material according to a set orientation to obtain a double-layer two-dimensional material with a relative angle of lattice orientations; or
directly growing a double-layer two-dimensional material with a relative angle of lattice orientations by a growth method, wherein the growth method comprises one of the following: chemical vapor deposition, molecular beam epitaxy, or physical vapor deposition.

3. The method according to claim 1, wherein the etching the double-layer two-dimensional material according to the determined nanoribbon orientation, nanoribbon width and inter-nanoribbon spacing comprises:
etching the double-layer two-dimensional material according to the determined nanoribbon orientation, nanoribbon width and inter-nanoribbon spacing by laser lithography, electron beam lithography, focused ion beam, high-energy electron beam, mask method or chemical etching.

4. The method according to claim 1, wherein the thermal excitation treatment comprises one or more of the following treatments: annealing, laser excitation, Joule heating and high-energy ray irradiation.

5. The method according to claim 1, wherein at least one layer of two-dimensional material in the double-layer two-dimensional material is a p-type doped or n-type doped two-dimensional material.

6. The method according to claim 1, wherein at least one layer of two-dimensional material in the double-layer two-dimensional material is a two-dimensional material with grain boundaries;
different regions of a same double-layer two-dimensional material prepared in the template preparation step have different relative angles of lattice orientations, and/or different sections of a same double-layer two-dimensional material nanoribbon in a lengthwise direction in the nanoribbon array etching step correspond to different nanoribbon widths;
the nanotube array obtained in the nanotube array generation step is an array of spliced nanotubes of different chirality.

7. The method according to claim 1, wherein the nanoribbon array etching step further comprises: determining a nanoribbon length according to the length of a nanotube to be prepared;
the etching the double-layer two-dimensional material according to the determined nanoribbon orientation, nanoribbon width, and inter-nanoribbon spacing comprises: etching the double-layer two-dimensional material according to the determined nanoribbon orientation, nanoribbon width, inter-nanoribbon spacing, and nanoribbon length.

8. The method according to claim 1, wherein the double-layer two-dimensional material is double-layer graphene, and the obtained nanotube array is a carbon nanotube array.

9. The method according to claim 8, wherein
the double-layer two-dimensional material with a relative angle of lattice orientations comprises two layers of graphene in which at least one layer has grain boundaries, and there are different relative angles between the two layers of graphene of different regions.
in the nanoribbon array etching step, different chiral parameters of carbon nanotubes to be prepared from two layers of graphene with different relative angles are determined, and nanoribbon orientation and different nanoribbon widths of different sections of the nanoribbon in the lengthwise direction corresponding to different chiral parameters is determined according to the determined different chiral parameters.

10. The method according to claim 1, wherein the double-layer two-dimensional material is a double-layer boron nitride two-dimensional material, a double-layer molybdenum sulfide two-dimensional material, a double-layer molybdenum selenide two-dimensional material or a double-layer tungsten sulfide two-dimensional material;
the obtained nanotube array is a boron nitride nanotube array, a molybdenum sulfide nanotube array, a molybdenum selenide nanotube array or a tungsten sulfide nanotube array.

11. The method according to claim 8, wherein
the nanoribbon orientation is given by an orientation formula as follows:
$${ψ}_{0} = 30 - arccos ( ( 2 n + m ) / 2 \sqrt{( {n}^{2} + mn + {m}^{2} )} ) ;$$
the nanoribbon width is given by a width formula as follow: w=0.5*a*\sqrt{n²+nm+m²};
where ψ₀ is the nanoribbon orientation, w is the nanoribbon width, a is the lattice constant of the two-dimensional material, and n and m are the chiral indices of a nanotube; or
the nanoribbon orientation and the nanoribbon width are obtained by introducing deviations into the orientation formula and the width formula, respectively.

12. A nanotube array prepared by a method for preparing a nanotube array, the method comprises the following steps:
a template preparation step: preparing a double-layer two-dimensional material with a relative angle of lattice orientations on a substrate, the double-layer two-dimensional material being used as a template;
a nanoribbon array etching step: determining chiral parameters of nanotubes to be prepared corresponding to the relative angle of lattice orientations of the double-layer two-dimensional material, determining a nanoribbon orientation and a nanoribbon width according to the determined chiral parameters, determining an inter-nanoribbon spacing according to the density of the nanotubes to be prepared and the nanoribbon width, and etching the double-layer two-dimensional material according to the determined nanoribbon orientation, nanoribbon width and inter-nanoribbon spacing to obtain a nanoribbon array of the double-layer two-dimensional material; and
a nanotube array generation step: performing thermal excitation treatment on the obtained nanoribbon array of the double-layer two-dimensional material to obtain a nanotube array.

13. The nanotube array according to claim 11, wherein the etching the double-layer two-dimensional material according to the determined nanoribbon orientation, nanoribbon width and inter-nanoribbon spacing comprises:
etching the double-layer two-dimensional material according to the determined nanoribbon orientation, nanoribbon width and inter-nanoribbon spacing by laser lithography, electron beam lithography, focused ion beam, high-energy electron beam, mask method or chemical etching.

14. The nanotube array according to claim 12, wherein the thermal excitation treatment comprises one or more of the following treatments: annealing, laser excitation, Joule heating and high-energy ray irradiation.

15. The nanotube array according to claim 1, wherein at least one layer of two-dimensional material in the double-layer two-dimensional material is a p-type doped or n-type doped two-dimensional material.

16. The nanotube array according to claim 12, wherein at least one layer of two-dimensional material in the double-layer two-dimensional material is a two-dimensional material with grain boundaries;
different regions of a same double-layer two-dimensional material prepared in the template preparation step have different relative angles of lattice orientations, and/or different sections of a same double-layer two-dimensional material nanoribbon in a lengthwise direction in the nanoribbon array etching step correspond to different nanoribbon widths;
the nanotube array obtained in the nanotube array generation step is an array of spliced nanotubes of different chirality.

17. The nanotube array according to claim 12, wherein the nanoribbon array etching step further comprises: determining a nanoribbon length according to the length of a nanotube to be prepared;
the etching the double-layer two-dimensional material according to the determined nanoribbon orientation, nanoribbon width, and inter-nanoribbon spacing comprises: etching the double-layer two-dimensional material according to the determined nanoribbon orientation, nanoribbon width, inter-nanoribbon spacing, and nanoribbon length.

18. The nanotube array according to claim 12, wherein the double-layer two-dimensional material is double-layer graphene, and the obtained nanotube array is a carbon nanotube array.

19. The nanotube array according to claim 18, wherein
the double-layer two-dimensional material with a relative angle of lattice orientations comprises two layers of graphene in which at least one layer has grain boundaries, and there are different relative angles between the two layers of graphene of different regions.
in the nanoribbon array etching step, different chiral parameters of carbon nanotubes to be prepared from two layers of graphene with different relative angles are determined, and nanoribbon orientation and different nanoribbon widths of different sections of the nanoribbon in the lengthwise direction corresponding to different chiral parameters is determined according to the determined different chiral parameters.

20. A carbon nanotube transistor prepared using a carbon nanotube array, the carbon nanotube array is prepared by a method comprising the following steps:
a template preparation step: preparing a double-layer two-dimensional material with a relative angle of lattice orientations on a substrate, the double-layer two-dimensional material being used as a template;
a nanoribbon array etching step: determining chiral parameters of nanotubes to be prepared corresponding to the relative angle of lattice orientations of the double-layer two-dimensional material, determining a nanoribbon orientation and a nanoribbon width according to the determined chiral parameters, determining an inter-nanoribbon spacing according to the density of the nanotubes to be prepared and the nanoribbon width, and etching the double-layer two-dimensional material according to the determined nanoribbon orientation, nanoribbon width and inter-nanoribbon spacing to obtain a nanoribbon array of the double-layer two-dimensional material; and
a nanotube array generation step: performing thermal excitation treatment on the obtained nanoribbon array of the double-layer two-dimensional material to obtain a nanotube array.
